(19) United States
(12) Patent Application Publication
(10) Pub. No.: US 2012/0092831 A1
(43) Pub. Date: Apr. 19, 2012

(54) HEAT DISSIPATION STRUCTURE FOR PORTABLE ELECTRONIC DEVICE

(75) Inventor: YAO-TING CHANG, Tu-Cheng (TW)

(73) Assignee: HON HAI PRECISION INDUSTRY CO., LTD., Tu-Cheng (TW)

(21) Appl. No.: 12/952,358

(22) Filed: Nov. 23, 2010

(30) Foreign Application Priority Data
Oct. 14, 2010 (TW) 99135039

(51) Int. Cl. H05K 7/20

(52) U.S. Cl. 361/704

(57) ABSTRACT

A heat dissipation structure for removing heat generated by electronic elements of a portable electronic device includes a base unit for mounting the electronic elements thereon and a heat dissipation unit detachably mounted on the base unit. The heat dissipation unit includes a base board and a number of thermal fins connected to the base board. The base board defines a receiving space therein, and a depth of the receiving space is larger than a thickness of each electronic element. The base board covers the electronic elements and the receiving space receives the electronic elements therein, such that heat generated by the electronic elements is transmitted to the thermal fins through the base board and dissipated by the thermal fins.

### BACKGROUND

1. Technical Field

The present disclosure relates to portable electronic devices, and particularly to a heat dissipation structure for a portable electronic device.

2. Description of Related Art

Portable electronic devices, such as mobile phones, personal digital assistants (PDA), and laptop computers, generally have circuit boards and electronic elements mounted on the circuit boards. When the portable electronic devices function, the electronic elements generate heat. Since excessive heat may damage the circuit boards and the electronic elements, heat dissipation structures are widely used in the portable electronic devices.

Most conventional heat dissipation structures for portable electronic devices are thermal fins. The thermal fins are assembled to circuit boards of the portable electronic devices and positioned above or adjacent to electronic elements mounted on the circuit boards for removing heat generated by the electronic elements. However, in assembly of the thermal fins, the thermal fins can possibly damage the electronic elements due to contact and friction. Furthermore, the thermal fins are generally difficult to detach from the circuit boards once they are assembled to the circuit boards. If the thermal fins need to be replaced or electronic elements covered by the thermal fins need to be repaired, the replacing/repairing operation will be complicated.

Therefore, there is room for improvement within the art.

### BRIEF DESCRIPTION OF THE DRAWINGS

Many aspects of the present heat dissipation structure can be better understood with reference to the following drawings. The components in the various drawings are not necessarily drawn to scale, the emphasis instead being placed upon clearly illustrating the principles of the present heat dissipation structure. Moreover, in the drawings, like reference numerals designate corresponding parts throughout the figures.

FIG. 1 is a disassembled view of a heat dissipation structure of a portable electronic device, according to an exemplary embodiment.

FIG. 2 is an assembled view the heat dissipation structure shown in FIG. 1.

### DETAILED DESCRIPTION

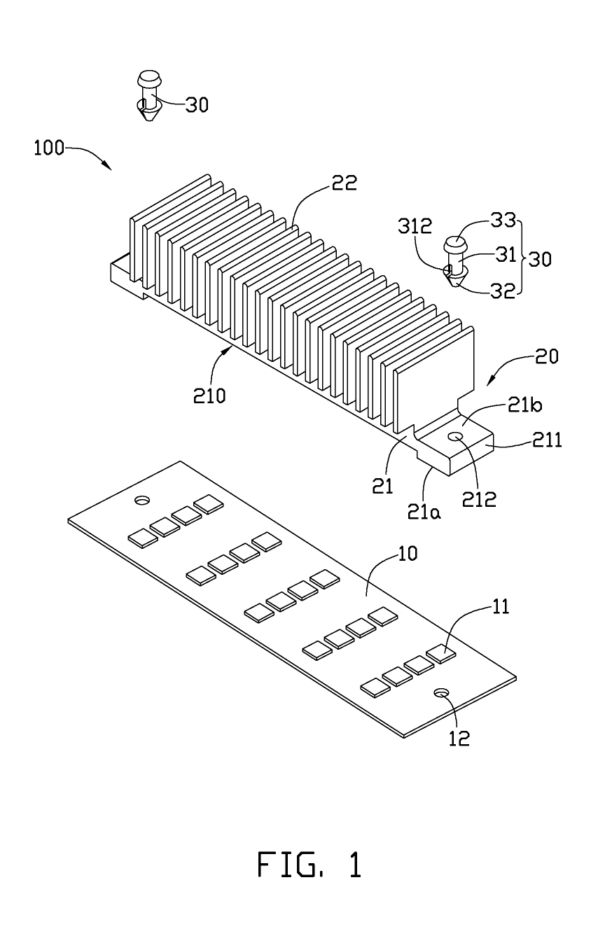

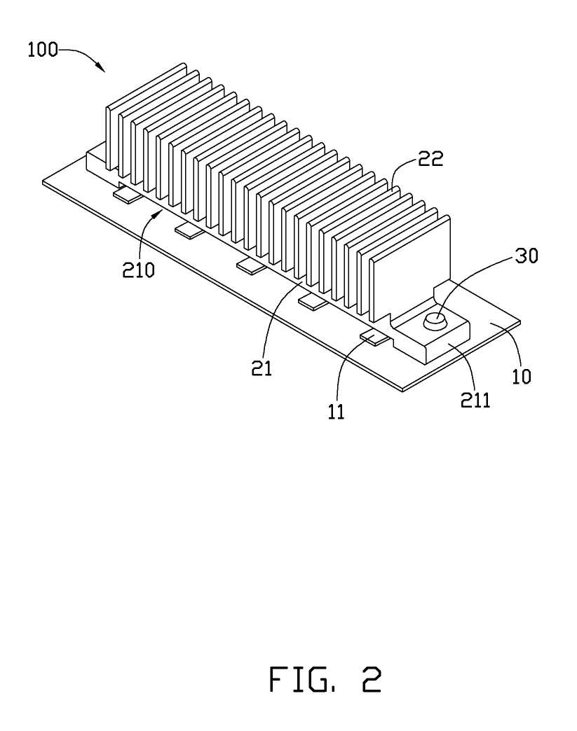

FIG. 1 and FIG. 2 show a heat dissipation structure 100, according to an exemplary embodiment. The heat dissipation structure 100 can be used in a portable electronic device, such as a mobile phone, a personal digital assistant (PDA), or a laptop computer, for dissipating heat generated by electronic elements of the portable electronic device.

The heat dissipation structure 100 includes a base unit 10, a heat dissipation unit 20, and retaining units 30. The base unit 10 is a planar panel for assembling a number of electronic elements 11 of the portable electronic device thereon. In this exemplary embodiment, the base unit 10 is a circuit board, and can be integrated with a conventional circuit board of a portable electronic device. The electronic elements 11 of the portable electronic device that need to be cooled are mounted on a middle portion of the base unit 10. Retaining holes 12 are defined in ends of the base unit 10.

The heat dissipation unit 20 is made of transcalent material. The heat dissipation unit 20 includes a base board 21 and a number of thermal fins 22. The base board 21 is a rectangular board that includes two opposite and parallel surfaces 21a and 21b. A middle portion of the surface 21a is recessed to form a receiving space 210, and a depth of the receiving space 210 is larger than a thickness of each electronic element 11. Correspondingly, retaining blocks 211 are formed on ends of the surface 21a, i.e., at ends of the base board 21. The retaining blocks 211 are thicker than other part of the base board 21, i.e., the part of the base board 21 corresponding to the receiving space 210. Assembly holes 212 are respectively defined in the retaining blocks 211, and the assembly holes 212 are positioned to respectively correspond to the retaining holes 12. When the heat dissipation unit 20 is positioned above the base unit 10, the assembly holes 212 and the receiving space 210 can be respectively aligned with the retaining holes 12 and the electronic elements 11. The thermal fins 22 are planar sheets perpendicularly and equidistantly connected to a middle portion of the surface 21b.

Each retaining unit 30 includes a main body 31, a fastening member 32, and a retaining member 33. The main body 31 is a cylinder, the fastening member 32 is a cone, and the retaining member 33 is a disk. One end of the main body 31 is coaxially connected to an undersurface of the fastening member 32, and another end of the main body 31 is coaxially connected to the retaining member 33. The main body 31 and the fastening member 32 are elastic. A length of the main body 31 is equal to a sum of a thickness of the retaining block 211 and a thickness of the base unit 10. A diameter of the main body 31 is substantially the same as the diameters of the retaining holes 12 and the assembly holes 212. A diameter of the retaining member 33 and a diameter of the undersurface of the fastening member 32 are both larger than the diameters of the retaining holes 12 and the assembly holes 212. A gap 312 is defined in the main body 31 and the fastening member 32.

In assembly, the heat dissipation unit 20 is positioned above the base unit 10, with the surface 21a positioned towards the base unit 10. The assembly holes 212 and the receiving space 210 are respectively aligned with the retaining holes 12 and the electronic elements 11. Thus, the heat dissipation unit 20 and the base unit 10 are driven to move towards each other, until the retaining blocks 211 contact the base unit 10 and the electronic elements 11 are received in the receiving space 210.

The fastening members 32 of the retaining units 30 are respectively aligned with the assembly holes 212, and the retaining units 30 are presses towards the heat dissipation unit 20. Thus, the fastening members 32 are respectively pressed to be deformed by the retaining blocks 211, and then are respectively inserted into the assembly holes 212 and the retaining holes 12. When the fastening members 32 pass through their corresponding assembly holes 212 and retaining holes 12, they rebound to resume their original shapes. Thus, the main bodies 31 are respectively received in their corresponding assembly holes 212 and retaining holes 12. In addition, the fastening members 32 and the retaining members 33 prevent the retaining units 30 from entirely passing through the assembly holes 212 and/or retaining holes 12 and then separating from the heat dissipation unit 20 and the base unit 11. In this way, the base unit 10 and the heat dissipation unit 20 are assembled together by the retaining units 30. In the above operations, the gaps 312 defined in the retaining members 30 can facilitate elastic deformation of the fastening members 32 and the main bodies 31, such that the fastening members 32 can easily pass through the assembly holes 212 and the retaining holes 12. The main bodies 31 can then be easily received in the assembly holes 212 and the retaining holes 12.

In above assembly process, since the electronic elements 11 are received in the receiving space 210 and covered by the heat dissipation unit 20, the assembling operations on the base unit 10, the retaining blocks 211, and the retaining units 30 are prevented from damaging the electronic elements 11. Furthermore, the heat dissipation unit 20 covering the electronic elements 11 can protect the electronic elements 11 from being banged or scraped by other elements in the portable electronic device.

In use, since the heat dissipation unit 10 is transcalent, heat generated by the electronic elements 11 can be easily transmitted to the thermal fins 22 through the base board 21 and dissipated by the thermal fins 22. When the heat dissipation unit 20 needs to be replaced or any electronic element 11 needs to be repaired, the retaining members 32 are compressed to be deformed, and then are inserted into corresponding retaining holes 12 and pushed to pass through corresponding retaining holes 12 and assembly holes 212. Thus, the heat dissipation structure 100 is disassembled, such that the replacing/repairing operations can be easily applied. After the replacing/repairing operations, the heat dissipation structure 100 can be assembled again according to above method.

Heat conductive glue can be applied on the base unit 10 and the heat dissipation unit 20 for improving heat conductive quality. The heat dissipation structure 100 can further include more or less retaining units 30, correspondingly, the base unit 10 and the heat dissipation unit 20 can define more or less retaining holes 12 and assembly holes 212 for assembling the retaining units 30 than shown in the FIGS.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A heat dissipation structure for removing heat generated by electronic elements of a portable electronic device, comprising:
a base unit for mounting the electronic elements thereon; and
a heat dissipation unit detachably mounted on the base unit; wherein the heat dissipation unit includes a base board and a number of thermal fins connected to the base board, the base board defining a receiving space therein, and a depth of the receiving space being larger than a thickness of each electronic element; the base board covering the electronic elements and the receiving space receiving the electronic elements therein, such that heat generated by the electronic elements is transmitted to the thermal fins through the base board and dissipated by the thermal fins.

2. The heat dissipation structure as claimed in claim 1, further comprising retaining units, wherein the base unit defines retaining holes and the heat dissipation unit defines assembly holes, the retaining units corresponding to the retaining holes and the assembly holes, each retaining unit received in its corresponding retaining hole and assembly hole to mount the heat dissipation unit on the base unit.

3. The heat dissipation structure as claimed in claim 2, wherein the base board includes two opposite surfaces, a part of one surface recesses to form the receiving space, and the thermal fins are connected to the other surface.

4. The heat dissipation structure as claimed in claim 3, wherein retaining blocks are formed on the surface defining the receiving space, and the assembly holes are respectively defined in the retaining blocks.

5. The heat dissipation structure as claimed in claim 4, wherein each retaining block is thicker than a part of the base board corresponding to the receiving space.

6. The heat dissipation structure as claimed in claim 4, wherein the receiving space is defined in a middle portion of the base board, and each retaining block is formed at an end of the base board.

7. The heat dissipation structure as claimed in claim 6, wherein the electronic elements are mounted on a middle portion of the base unit, and the retaining holes are respectively defined in ends of the base unit.

8. The heat dissipation structure as claimed in claim 2, wherein each retaining unit includes a main body, a fastening member, and a retaining member; the fastening member and the retaining member respectively connected to ends of the main body; a diameter of the main body being substantially the same as the diameters of corresponding retaining hole and assembly hole, and diameters of both the retaining member and the fastening member being larger than the diameters of the retaining hole and the assembly hole; the main body received in the retaining hole and the assembly hole, and the fastening member and the retaining members prevent the retaining unit from entirely passing through the assembly hole and/or the retaining hole and thereby disassembling the heat dissipation structure.

9. The heat dissipation structure as claimed in claim 8, wherein the main body is a cylinder, the fastening member is a cone, and the retaining member is a disk; one end of the main body coaxially connected to an undersurface of the fastening member, and another end of the main body coaxially connected to the retaining member.

10. The heat dissipation structure as claimed in claim 8, wherein the fastening member is elastic and is capable of being elastically deformed to pass through corresponding retaining hole and assembly hole and then rebounding.

11. The heat dissipation structure as claimed in claim 10, wherein the main body is elastic.

12. The heat dissipation structure as claimed in claim 11, wherein a gap is defined in the fastening member to facilitate elastic deformation of the fastening member, and thereby facilitating the fastening member passing through corresponding assembly hole and retaining hole.

13. The heat dissipation structure as claimed in claim 12, wherein the gap is also defined in the main body to facilitate elastic deformation of the main body, and thereby facilitating the main bodies being received in corresponding assembly hole and the retaining hole.

14. The heat dissipation structure as claimed in claim 8, wherein a length of the main body is equal to a sum of a thickness of the retaining block and a thickness of the base unit.

15. The heat dissipation structure as claimed in claim 1, wherein heat conduct glue is spread on the base unit and the heat dissipation unit.
